(19) United States
(12) Patent Application Publication
(10) Pub. No.: US 2009/0160019 A1
(43) Pub. Date: Jun. 25, 2009

(54) SEMICONDUCTOR CAPACITOR

(75) Inventor: Ming-Tzong Yang, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/960,950

(22) Filed: Dec. 20, 2007

(51) Int. Cl. H01L 29/00

(52) U.S. Cl. 257/532; 257/E29.001

(57) ABSTRACT

A capacitor structure is provided. The capacitor structure includes a plurality of first conductive lines paralleled disposed in a conductive layer on a substrate, wherein the first conductive lines are isolated to each other in the conductive layer and are grouped into a first electrode group and a second electrode group, an insulating layer formed on the first conductive lines and in the space between the first conductive lines, a second conductive line formed on the insulating layer electrically connected to the first conductive lines of the first electrode group, and a third conductive line formed on the insulating layer electrically connected to the first conductive lines of the second electrode group.

### BACKGROUND OF THE INVENTION

1. Field of the Invention

The invention relates to a semiconductor device structure and in particular to a capacitor structure.

2. Description of the Related Art

Capacitors are critical components in integrated circuit devices. As devices become smaller and circuit density increases, it becomes more critical that capacitors maintain their capacitance while taking up less area on the integrated circuit. Both polysilicon and metal-oxide-metal (MOM) capacitors have been used in the art. Metal-oxide-metal capacitors are popular because their minimal capacitive loss results in a high quality capacitor.

Referring to FIG. 1, a conventional MOM capacitor structure is disclosed. The MOM capacitor structure includes a plurality of parallel metal lines 2 disposed on a substrate 1. The even metal lines 2′ are connected with each other to form a comb structure 3. Also, the odd metal lines 2″ are connected to form another comb structure 4. Additionally, the metal lines 2 are surrounded by another metal line 5 to shield substrate charges.

### BRIEF SUMMARY OF THE INVENTION

The invention provides a capacitor comprising a plurality of first conductive lines paralleled disposed in a conductive layer on a substrate, wherein the first conductive lines are isolated to get less parasitic to each other in the conductive layer and are grouped into a first electrode group and a second electrode group, an insulating layer formed on the first conductive lines and in the space between the first conductive lines, a second conductive line formed on the insulating layer electrically connected to the first conductive lines of the first electrode group, and a third conductive line formed on the insulating layer electrically connected to the first conductive lines of the second electrode group.

The invention provides another capacitor comprising a plurality of first conductive lines paralleled disposed in a conductive layer on a substrate, wherein the first conductive lines are isolated to each other in the conductive layer and are grouped into a first electrode group and a second electrode group, a second conductive line disposed in the conductive layer electrically connected to the first conductive lines of the first electrode group, an insulating layer formed on the first and second conductive lines, and formed in the space between the first conductive lines, and a third conductive line formed on the insulating layer electrically connected to the first conductive lines of the second electrode group.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a top view of a conventional MOM capacitor structure.

FIG. 2A is a top view of a MOM capacitor structure of the invention.

FIG. 2B is a cross section of the MOM capacitor structure of FIG. 2A along 2B-2B line.

FIG. 2C is a cross section of the MOM capacitor structure of FIG. 2A along 2B′-2B′ line.

FIGS. 3 and 4 are top views of a via structure of the invention.

FIG. 5A is a top view of a MOM capacitor structure of the invention.

FIG. 5B is a cross section of the MOM capacitor structure of FIG. 5A along 5B-5B line.

FIG. 6 is a top view of a MOM capacitor structure of the invention.

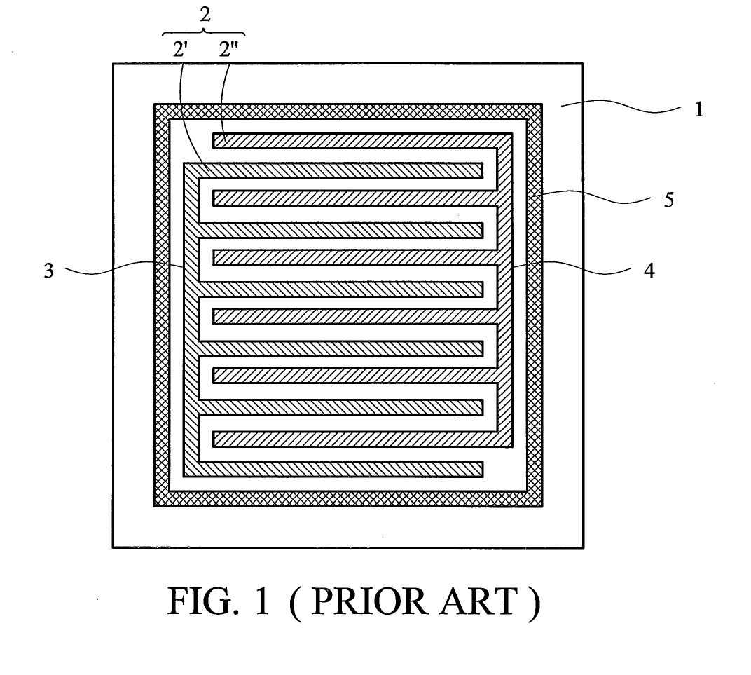

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a capacitor structure having a plurality of isolated first metal lines paralleled disposed on a substrate, an insulating layer (e.g. oxide layer) formed on the first metal lines and formed in the space between the first metal lines, a second metal line electrically connected to the odd first metal lines (a first electrode group), and a third metal line electrically connected to the even first metal lines (a second electrode group). The second metal line and the third metal line are disposed on the insulating layer, and electrically connected to the odd first metal lines (the first electrode group) and the even first metal lines (the second electrode group), respectively.

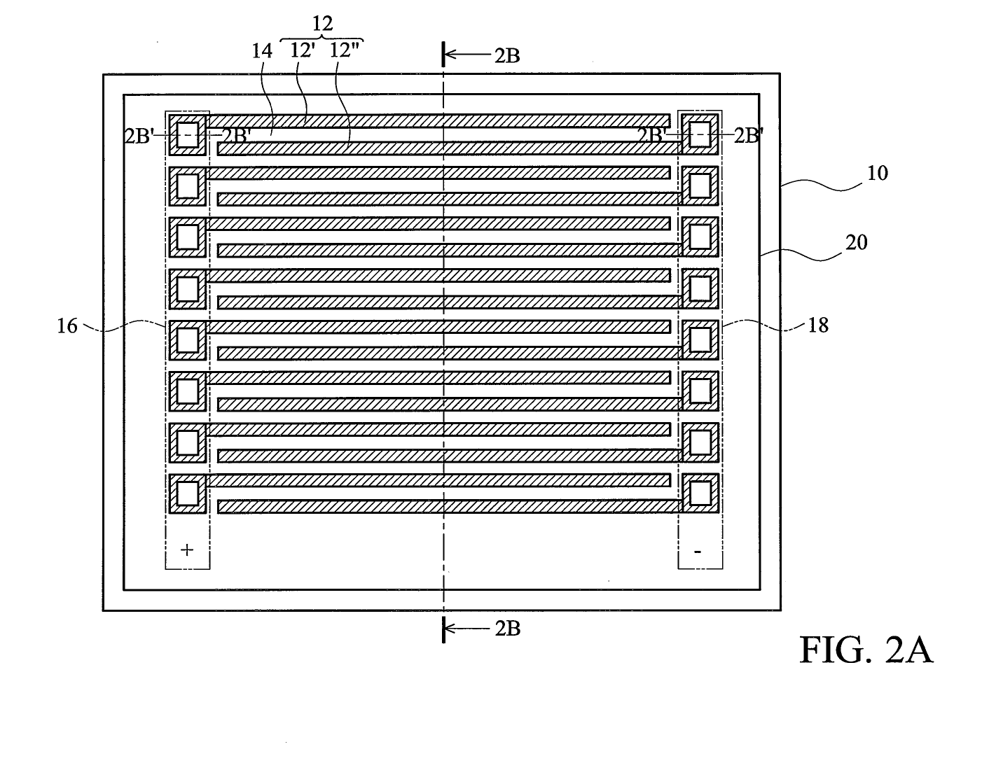

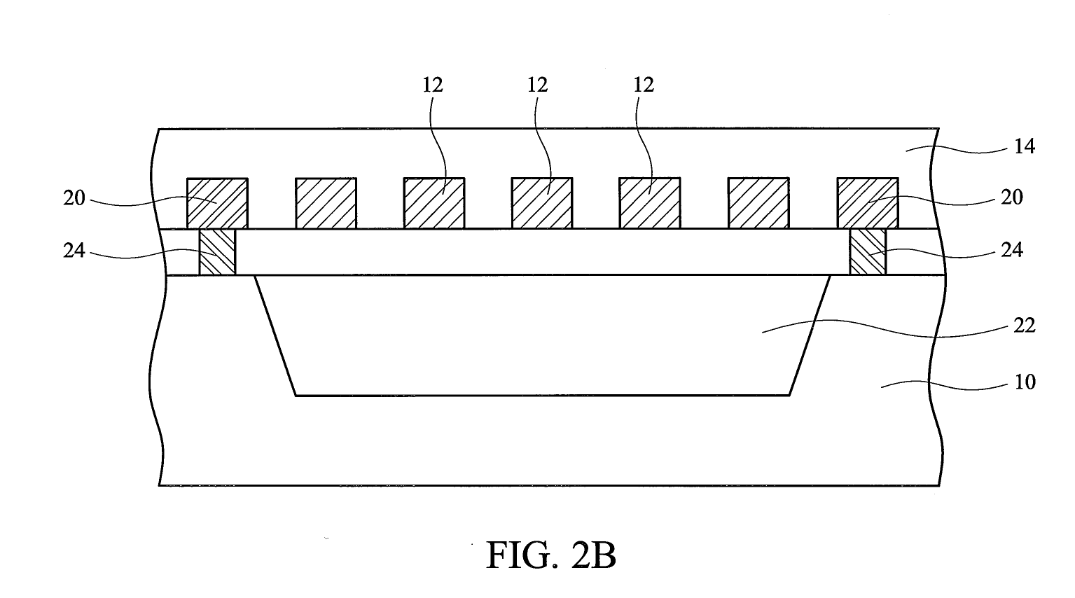

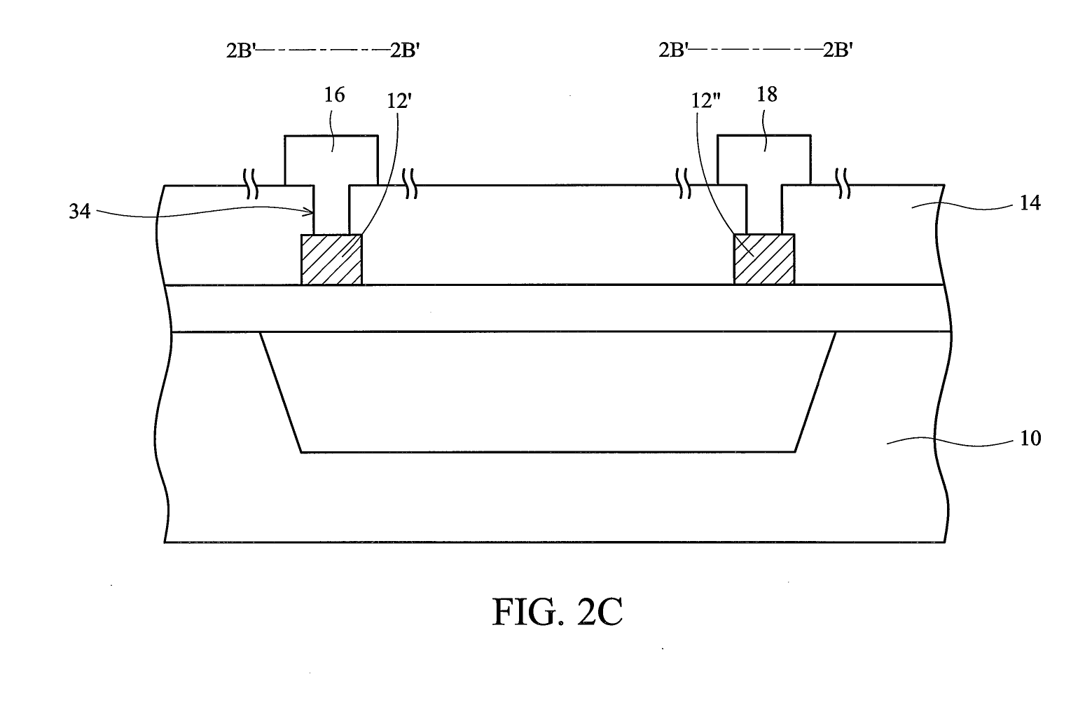

In a first embodiment, a metal-oxide-metal (MOM) capacitor structure is disclosed, as shown in FIGS. 2A, 2B and 2C. FIG. 2A is a top view of the MOM capacitor structure of the invention. FIG. 2B is a cross section of the MOM capacitor structure of FIG. 2A along 2B-2B line. FIG. 2C is a cross section of the MOM capacitor structure of FIG. 2A along 2B′-2B′ line. Referring to FIG. 2A, the MOM capacitor structure has a plurality of first metal lines 12 disposed in a conductive layer on a substrate 10 and an oxide layer 14 sandwiched between the first metal lines 12. Significantly, the first metal lines 12 are parallel and isolated from one another in the conductive layer via an insulating material. A second metal line 16 is disposed on the insulating material and electrically connected to the odd first metal lines 12′ (a first electrode group). A third metal line 18 is disposed on the insulating material and electrically connected to the even first metal lines 12″ (a second electrode group). The second metal line 16 is opposite to the third metal line 18.

The first metal lines 12 may further be surrounded by a fourth metal line 20 serving as shielding.

Referring to FIG. 2B, the substrate 10 may include a shallow trench isolation (STI) 22 serving as shielding. The first metal lines 12 are disposed on the substrate 10. The oxide layer 14 is formed over and filled the space between the first metal lines 12. The fourth metal line 20 disposed around the first metal lines 12 is electrically connected to the substrate 10 through a via plug 24. Referring to FIG. 2C, a via structure 34 is formed in the oxide layer 14 corresponding to each first metal line 12 serving as an electrical connection between the first metal lines 12 and the second metal line 16 or the third metal line 18.

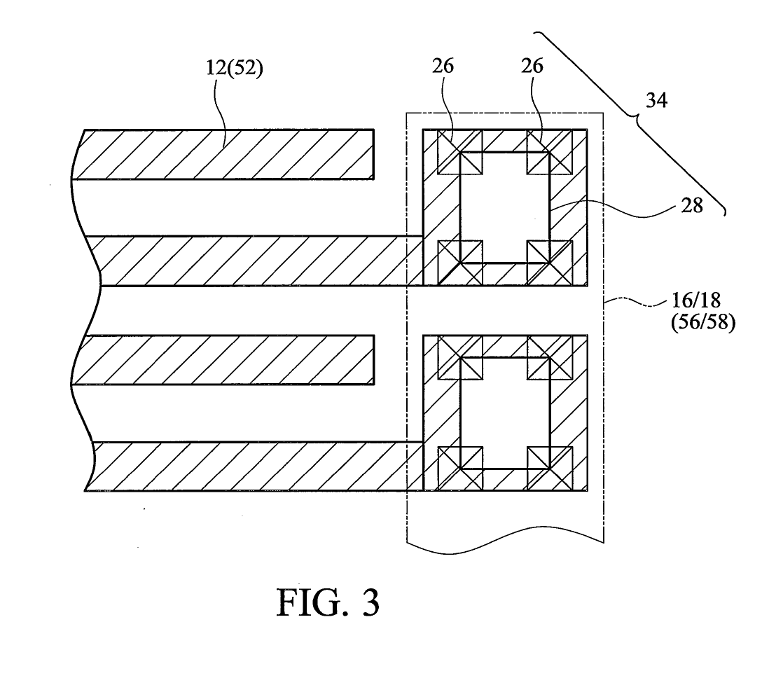

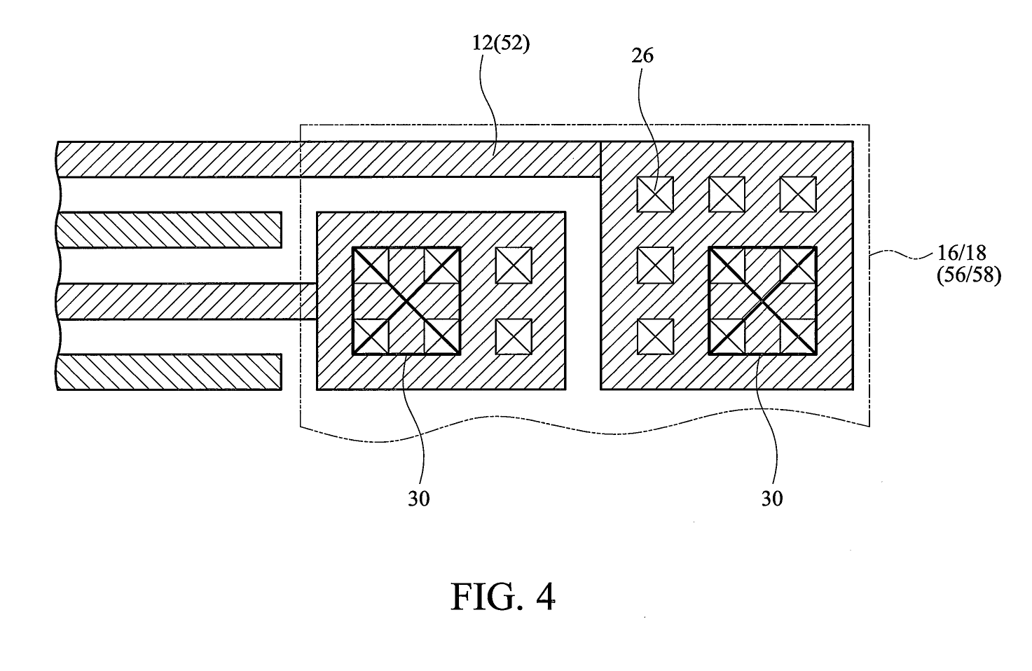

The top views of the via structure 34 are shown in FIGS. 3 and 4. In FIG. 3, the via structure 34 includes one or more via plugs 26, such as four via plugs. If the second or third metal line 16/18 become thicker, a larger via 28 (2× pitch) or 30 (4× pitch) is required, as shown in FIG. 3 and FIG. 4, respectively.

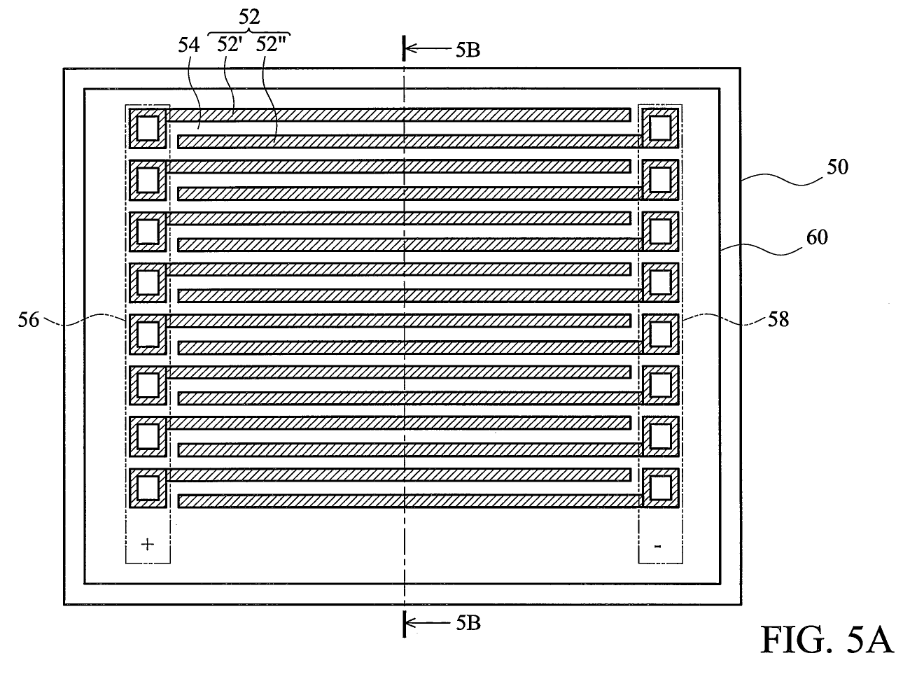

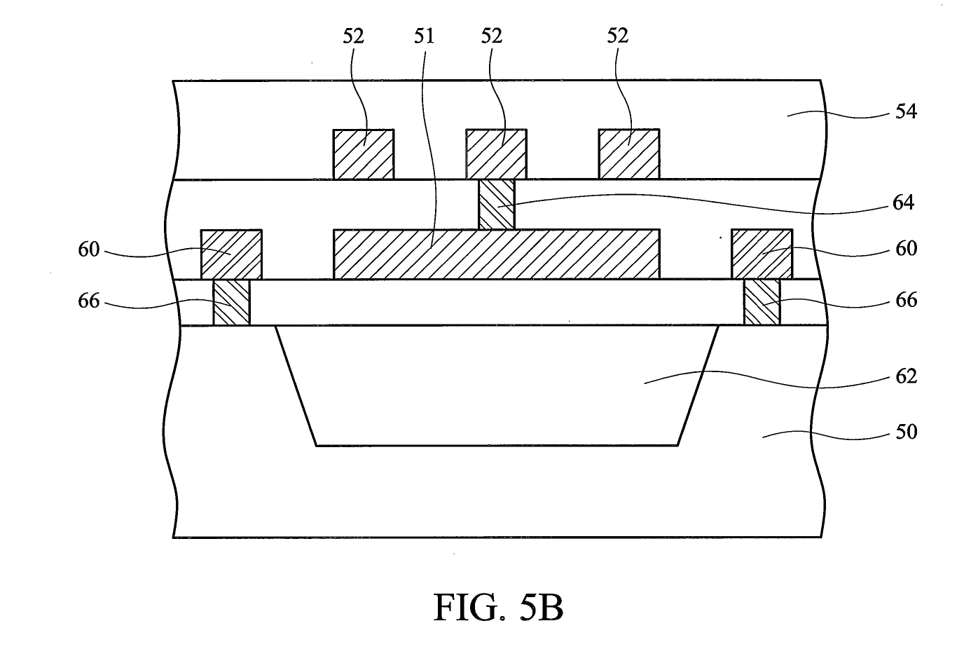

In the second embodiment of the invention, another metal-oxide-metal (MOM) capacitor structure is disclosed, as shown in FIGS. 5A and 5B. FIG. 5A is a top view of the MOM capacitor structure. FIG. 5A is similar to FIG. 2A. FIG. 5B is a cross section of the MOM capacitor structure of FIG. 5A along 5B-5B line. The first and second embodiments of the invention differ in the addition of a metal shielding layer between metal lines and substrate. Referring to FIG. 5A and 5B, the MOM capacitor structure include a metal layer 51 formed on a substrate 50. An insulating layer 53 is disposed on the metal layer 51. A plurality of first metal lines 52 disposed on the insulating layer 53, and an oxide layer 54 sandwiched between the first metal lines 52. Significantly, the first metal lines 52 are grouped into a first electrode group (odd metal lines 52′) and a second electrode group (even metal lines 52″) and isolated from one another. A second metal line 56 is disposed on the oxide layer 54 and electrically connected to the odd first metal lines 52″. A third metal line 58 is disposed on the oxide layer and electrically connected to the even first metal lines 52″. The second metal line 56 is opposite to the third metal line 58.

The first metal lines 52 may further be surrounded by a fourth metal line 60 serving as shielding.

Referring to FIG. 5B, the substrate 50 may has a shallow trench isolation (STI) 62 serving as shielding. Compared to FIG. 2B, a metal layer 51 serving as shielding is formed between the first metal lines 52 and the substrate 50 and electrically connected to one of the first metal lines 52 through a via 64. In particular, the metal layer 51 is electrically connected to one of the first electrode group and the second electrode group. The fourth metal line 60 disposed around the first metal lines 52 is electrically connected to the substrate 50 through a via 66.

The metal layer 51 can effectively shield substrate charges, stabilizing capacitor operation.

Similar to FIGS. 3 and 4, a via structure having one or more vias corresponding to each first metal line 52 serving as an electrical connection between the first metal lines 52 and the second and third metal lines is formed in the oxide layer 54. If the second or third metal line 56/58 become thicker, a larger via is also required.

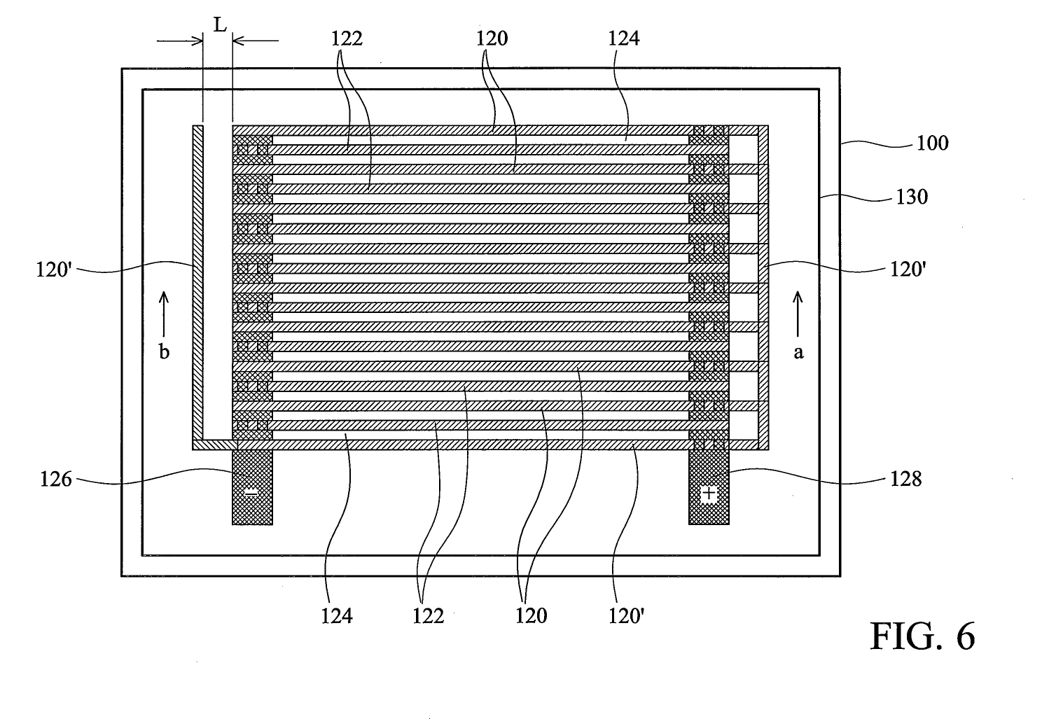

In the third embodiment, another metal-oxide-metal (MOM) capacitor structure is disclosed, as shown in FIG. 6. FIG. 6 is a top view of the MOM capacitor structure. Referring to FIG. 6, the MOM capacitor structure includes a plurality of first metal lines 120 disposed on a substrate 100, a plurality of second metal lines 122 disposed between the first metal lines 120, and an oxide layer 124 sandwiched between the first and second metal lines. The out first metal line 120′ is extended toward a first direction a to connect one end of the remaining first metal lines 120 and extended toward a second direction b to leave a specific distance L from the other end of the remaining first metal lines 120. The second metal lines 122 are isolated one another. A third metal line 126 is disposed on the oxide layer 124 and electrically connected to the second metal lines 122 via via plugs. The first direction a is parallel to the second direction b.

Optionally, a fourth metal line 128 is electrically connected to the first metal lines 120. Similarly, the third metal line 126 and the fourth metal line 128 are electrically connected to the second metal lines 122 and the first metal lines 120, respectively, through vias, as shown in FIGS. 3 and 4.

Additionally, a fifth metal line 130 is disposed around the first metal lines 120 and electrically connected to the substrate 100. To shield substrate charges, a metal layer (not shown) may further be formed between the first and second metal lines and the substrate 100 and electrically connected to one of the first and second metal lines, as shown in FIG. 5B.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A capacitor structure, comprising:
a plurality of first conductive lines paralleled disposed in a conductive layer on a substrate, wherein the first conductive lines are isolated to each other in the conductive layer and are grouped into a first electrode group and a second electrode group;
an insulating layer formed on the first conductive lines and in the space between the first conductive lines;
a second conductive line formed on the insulating layer electrically connected to the first conductive lines of the first electrode group; and
a third conductive line formed on the insulating layer electrically connected to the first conductive lines of the second electrode group.

2. The capacitor structure as claimed in claim 1, further comprising one or more via plugs formed in the insulating layer corresponding to each first conductive line.

3. The capacitor structure as claimed in claim 2, wherein the second conductive line is electrically connected to the first conductive lines of the first electrode group through the via plugs, and the third conductive line electrically connected to the first conductive lines of the second electrode group through the via plugs, respectively.

4. The capacitor structure as claimed in claim 1, further comprising a fourth conductive line disposed in the conductive layer around the first conductive lines.

5. The capacitor structure as claimed in claim 4, wherein the fourth conductive line is electrically connected to the substrate.

6. The capacitor structure as claimed in claim 1, further comprising a conductive shielding layer formed between the conductive layer and the substrate.

7. The capacitor structure as claimed in claim 6, wherein the conductive shielding layer is electrically connected to one of the first electrode group and the second electrode group.

8. The capacitor structure as claimed in claim 1, wherein the first conductive lines of the first electrode group and the first conductive lines of the second electrode group are disposed alternately.

9. A capacitor structure, comprising:
a plurality of first conductive lines paralleled disposed in a conductive layer on a substrate, wherein the first conductive lines are isolated to each other in the conductive layer and are grouped into a first electrode group and a second electrode group;
a second conductive line disposed in the conductive layer electrically connected to the first conductive lines of the first electrode group;
an insulating layer formed on the first and second conductive lines, and formed in the space between the first conductive lines; and
a third conductive line formed on the insulating layer electrically connected to the first conductive lines of the second electrode group.

10. The capacitor structure as claimed in claim 9, further comprising one or more via plugs formed in the insulating layer corresponding to each first conductive line.

11. The capacitor structure as claimed in claim 10, wherein the third conductive line electrically connected to the first conductive lines of the second electrode group through the via plugs.

12. The capacitor structure as claimed in claim 9, further comprising a fourth conductive line disposed in the conductive layer around the first conductive lines.

13. The capacitor structure as claimed in claim 12, wherein the fourth conductive line is electrically connected to the substrate.

14. The capacitor structure as claimed in claim 9, further comprising a conductive shielding layer formed between the conductive layer and the substrate.

15. The capacitor structure as claimed in claim 14, wherein the conductive shielding layer is electrically connected to one of the first electrode group and the second electrode group.

16. The capacitor structure as claimed in claim 9, wherein the first conductive lines of the first electrode group and the first conductive lines of the second electrode group are disposed alternately.
